(19) United States
(12) Patent Application Publication
(10) Pub. No.: US 2014/0360952 A1
(43) Pub. Date: Dec. 11, 2014

(54) MOUNTING APPARATUS FOR EXPANSION CARDS

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: ZHAN-YANG LI, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 14/155,643

(22) Filed: Jan. 15, 2014

(30) Foreign Application Priority Data
Jun. 6, 2013 (CN) 2013102229966

(51) Int. Cl. H05K 7/14; H05K 7/18

(52) U.S. Cl. CPC H05K 7/1417; H05K 7/183; H05K 7/1405
USPC 211/41.17

(57) ABSTRACT

A mounting apparatus includes a mounting case, a mounting piece, and a securing member. The mounting case includes a bottom plate. A mounting portion is located on the bottom plate. The mounting piece is used to secure a front end of an expansion card to the mounting case. The securing member includes a first securing panel, a second securing panel, and a rotating portion. The first securing panel and the second securing panel are connected to the mounting portion. The second securing panel is rotatable about the rotating portion to engage with the first securing panel, so that the first securing panel and the second securing panel cooperatively bind a rear end portion of the expansion card.

### BACKGROUND

1. Technical Field

The present disclosure relates to mounting apparatuses, and particularly to a mounting apparatus for securing expansion cards in an electronic device.

2. Description of Related Art

Computer systems usually include multiple expansion cards, such as sound cards, video cards, and graphics cards, for enhancing capabilities of the computer system. However, if an expansion card is relatively long, only one end of the expansion card may be secured to a front wall of a computer system enclosure, so the expansion card may not be stably secured. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an embodiment of a mounting apparatus and an expansion card.

FIG. 2 is an isometric view of a securing member of the mounting apparatus of FIG. 1.

FIG. 3 is a cutaway view of a mounting case of the mounting apparatus of FIG. 1.

FIG. 4 is an assembled view of the mounting apparatus and the expansion card of FIG. 1, with the securing member in an unlocked position.

FIG. 5 is a cross-sectional view of the mounting apparatus of FIG. 4, taken along line V-V.

FIG. 6 is similar to FIG. 4, but the securing member is in a locked position.

FIG. 7 is a cross-sectional view of the mounting apparatus of FIG. 6, taken along line VII-VII.

FIG. 8 is similar to FIG. 6, but viewed from a different aspect.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

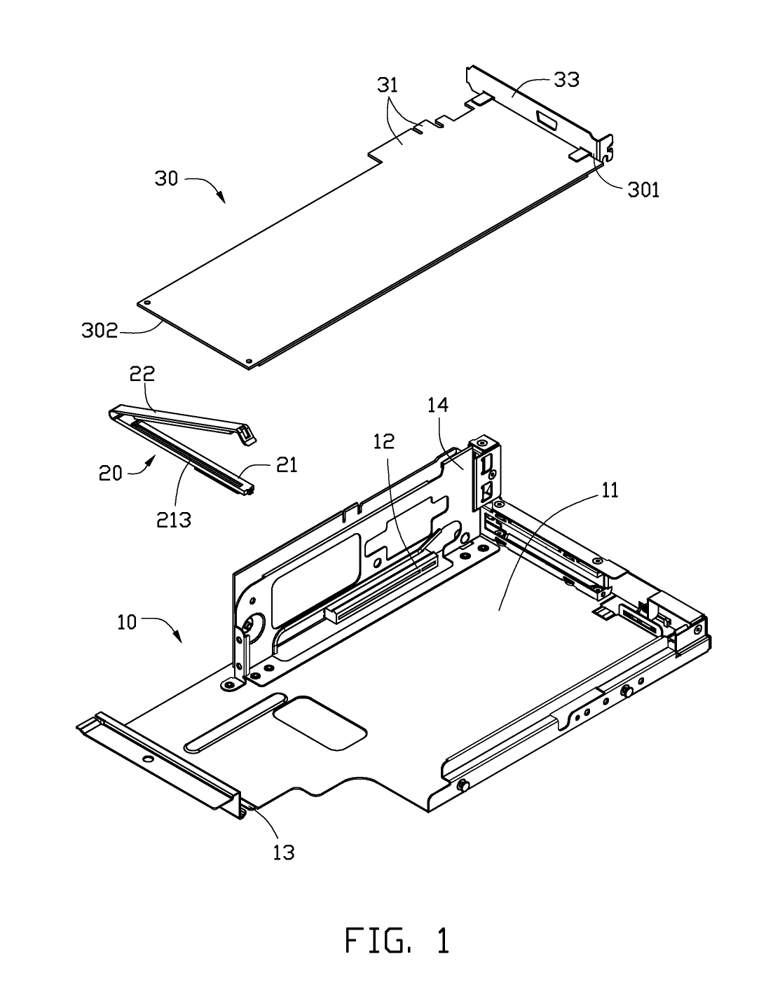

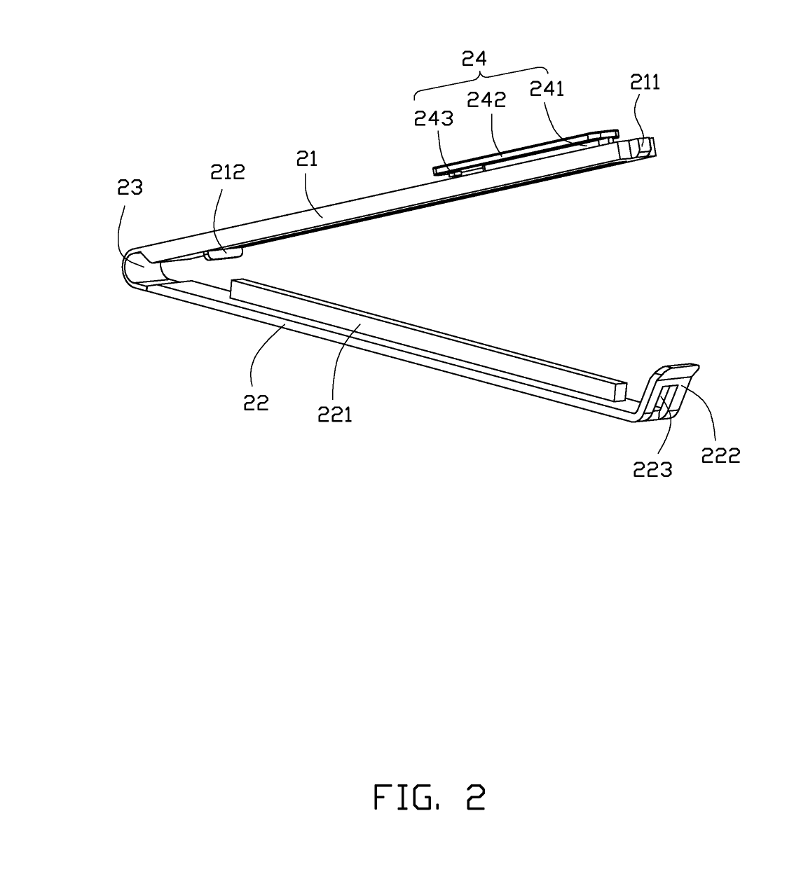

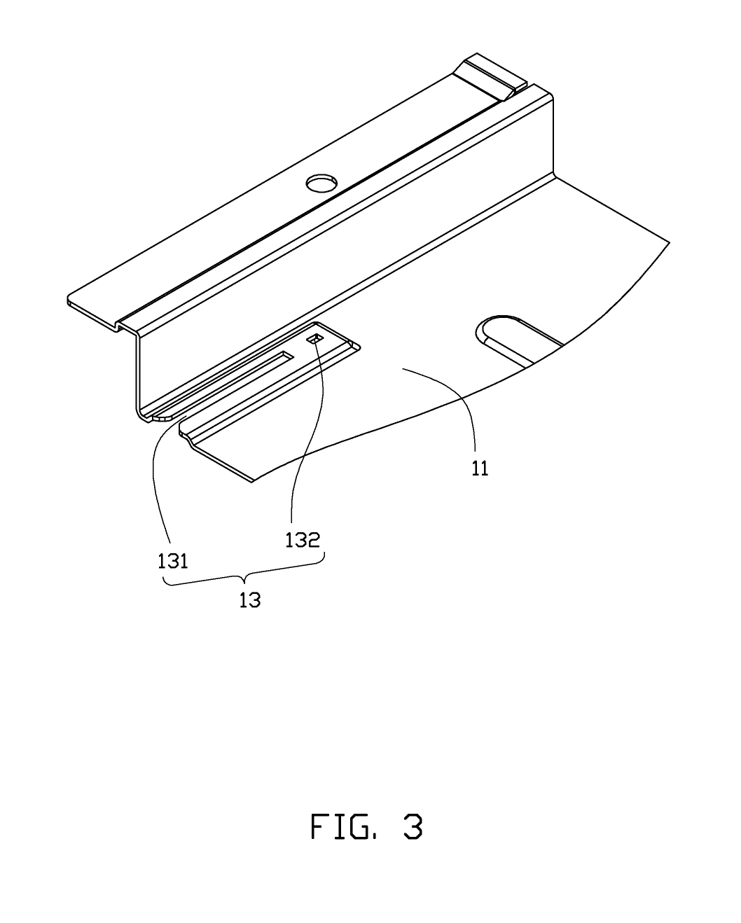

FIGS. 1-3 illustrate an embodiment of a mounting apparatus for securing an expansion card 30. The mounting apparatus comprises a mounting case 10 and a securing member 20. The expansion card 30 can be, but is not limited to, a sound card, a video card, a graphics card, or other peripheral component interconnection card.

The expansion card 30 comprises a front end 301 and a rear end 302 opposite from the front end 301. A mounting piece 33 is located at the front end 301. An inserting portion 31 protrudes from the expansion card 30.

The mounting case 10 comprises a bottom plate 11 and a side plate 14 connected substantially perpendicular to the bottom plate 11. A mounting portion 13 is located on the bottom plate 11. The mounting portion 13 defines a sliding slot 131 and a fixing hole 132 adjacent to the sliding slot 131. In one embodiment, the sliding slot 131 is substantially U-shaped, and an inserting slot 12 is defined in the side plate 14.

The securing member 20 comprises a first securing panel 21, a second securing panel 22, and a rotating portion 23 connected to the first securing panel 21 and the second securing panel 22. A clipping block 211 is located at a free end of the first securing panel 21. An inner surface of the first securing panel 21 forms a positioning piece 212 and defines an engaging slot 213. A fixing portion 24 is located on an outer surface of the first securing panel 21. The fixing portion 24 comprises a sliding portion 241, a blocking piece 242, and a fixing block 243. The sliding portion 241 is connected to the first securing panel 21 and the blocking piece 242. In one embodiment, the blocking piece 242 is substantially parallel to the first securing panel 21, and the fixing block 243 protrudes from the blocking piece 242 toward the first securing panel 21. A clipping piece 222 defining a clipping hole 223 extends from a free end of the second securing panel 22. An engaging portion 221 is located on the second securing panel 22.

The first securing panel 21 is rotatable about the rotating portion 23, so that the securing member 20 is in a locked position or an unlocked position. In the locked position, the engaging portion 221 is received through the engaging slot 213, and the clipping block 211 is received through the clipping hole 223. In the unlock position, the engaging portion 221 is removed from the engaging slot 213, and the clipping block 211 is removed from the clipping hole 223.

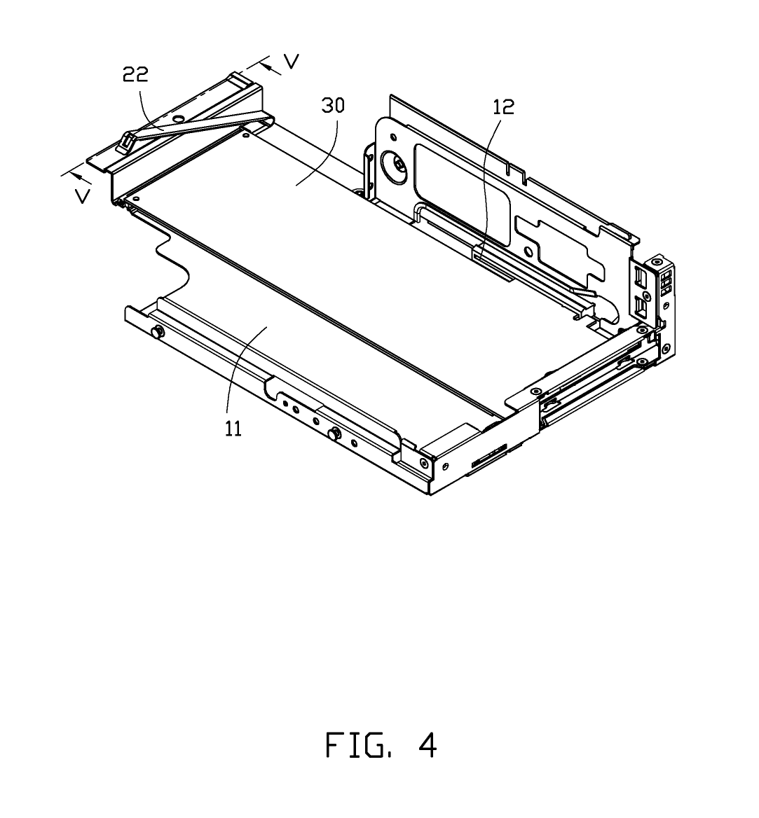

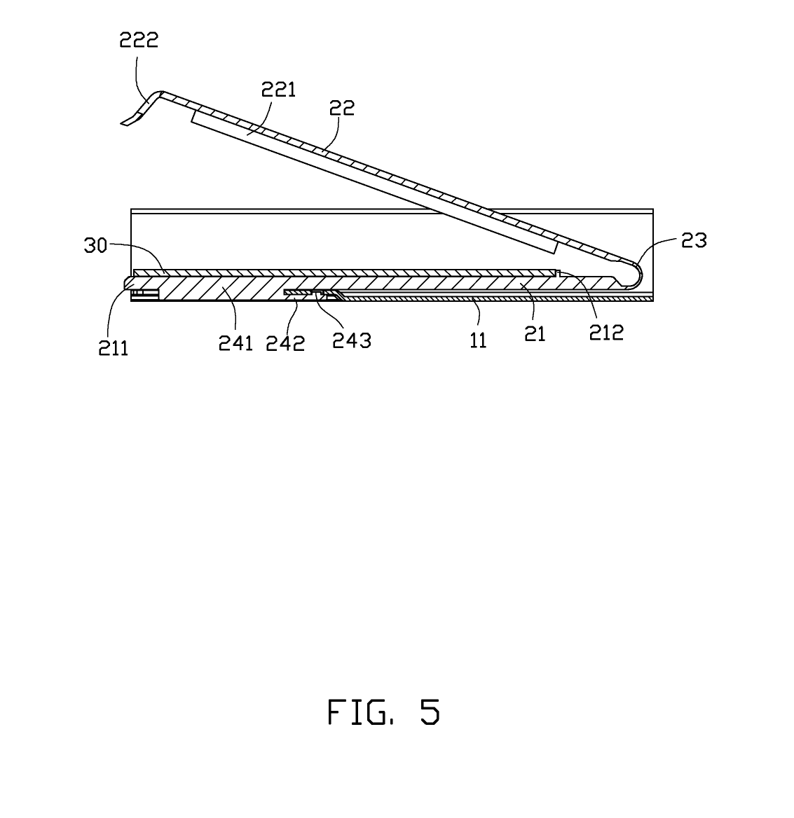

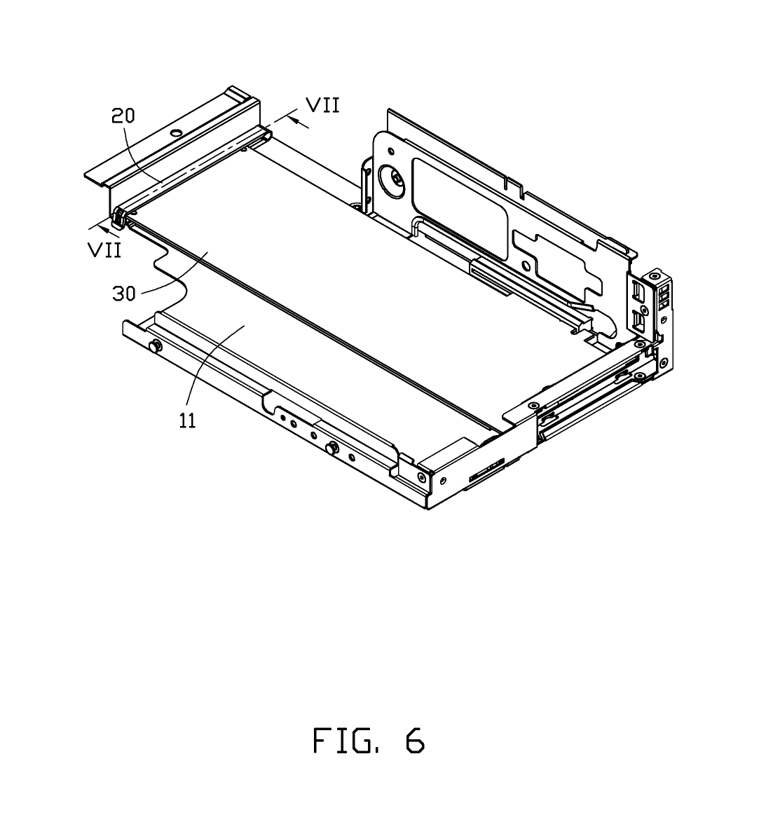

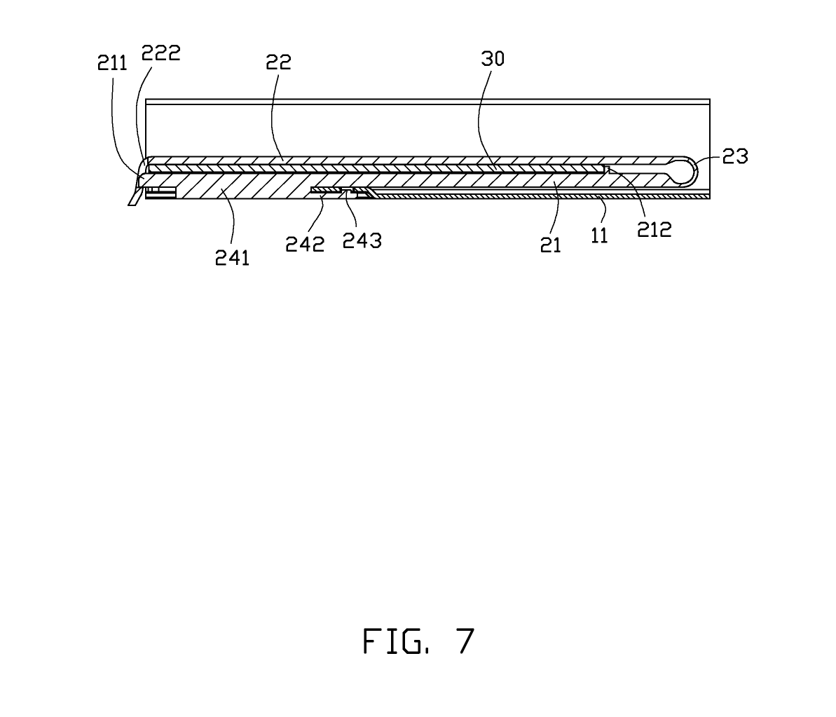

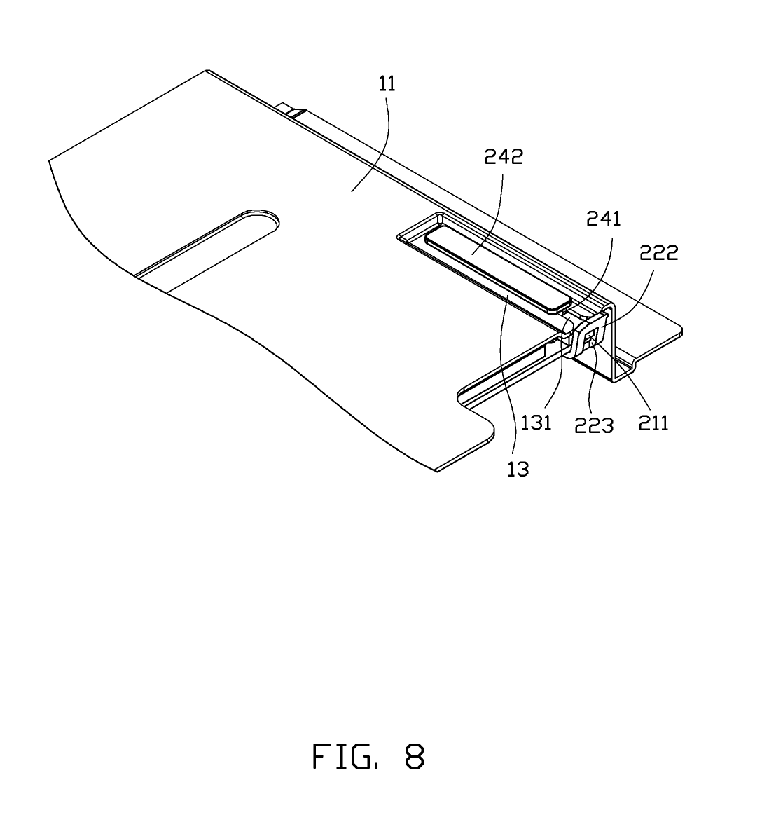

FIGS. 4-8 illustrate that in assembly, the sliding portion 241 is aligned with an entrance of the sliding slot 131. The securing member 20 is slid along the bottom plate 11, until the fixing block 243 is received through the fixing hole 132. In this state, the first securing panel 21 is located on an inner surface of the bottom plate 11, and the blocking piece 242 is latched to an outer surface of the bottom plate 11 to prevent the first securing panel 21 from being removed from the bottom plate 11. Therefore, the securing member 20 is secured to the mounting case 10, and the securing member 20 is in the unlock position.

The mounting piece 33 of the expansion card 30 is secured to the mounting case 10 by means, such as clips, to secure the expansion card 30 to the mounting case 10. Such that the inserting portion 31 is received through the inserting slot 12, and the rear end 302 abuts the first securing position 21. The positioning piece 243 abuts one side of the expansion card 30, to prevent the expansion card 30 from moving in a direction that is substantially parallel to the bottom plate 11. The engaging slot 213 is exposed, so when the second securing panel 22 is rotated relative to the first securing panel 21, the engaging portion 221 is received in the engaging slot 213, and the clipping block 211 is received in the clipping hole 223. Thus, the expansion card 30 is stably secured to the mounting case 10.

In disassembly, the clipping block 211 is removed from the clipping hole 223, the engaging portion 221 is removed from the engaging slot 213, the second securing panel 22 is rotated relative to the first securing panel 21, and the mounting piece 33 is detached from the mounting case 10. Thus, the expansion card 30 can be removed from the mounting case 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
a mounting case comprising a bottom plate; a mounting portion located on the bottom plate;
a mounting piece configured to be secured to a front end of an expansion card; the mounting piece is secured to the mounting case;
a securing member comprising a first securing panel, a second securing panel, and a rotating portion connected to the first securing panel and the second securing panel; the first securing panel is secured to the mounting portion;
wherein the second securing panel is rotatable about the rotating portion to engage with the first securing panel, so that the first securing panel and the second securing panel together sandwich a rear end of the expansion card therebetween.

2. The mounting apparatus of claim 1, wherein the first securing panel comprises a clipping block, the second securing panel defines a clipping hole, and the clipping block is clipped in the clipping hole.

3. The mounting apparatus of claim 2, wherein a clipping piece extends from the second securing panel and at an angle at the second securing panel, and the clipping hole is defined in the clipping piece.

4. The mounting apparatus of claim 1, wherein the first securing panel defines an engaging slot, and the second securing panel comprises an engaging portion engaged in the engaging slot.

5. The mounting apparatus of claim 1, wherein a positioning piece substantially perpendicular extends from the first securing panel, and the positioning piece configured to abut the expansion card to prevent the expansion card from moving in a direction that is substantially parallel to the bottom plate.

6. The mounting apparatus of claim 1, wherein a fixing portion is located on the first securing panel and comprises a sliding portion extending from the first securing panel, the mounting portion comprises a sliding slot, and the sliding portion is slidably received in the sliding slot.

7. The mounting apparatus of claim 6, wherein the sliding slot is substantially U-shaped.

8. The mounting apparatus of claim 6, wherein the fixing portion further comprises a blocking piece connected to the sliding portion, the blocking piece is substantially parallel to the first securing panel, the first securing panel abuts an inner surface of the bottom plate, and the blocking piece abuts an outer surface of the bottom plate, to prevent the securing member from moving in a direction that is substantially perpendicular to the bottom plate.

9. The mounting apparatus of claim 6, wherein the mounting portion comprises a fixing hole, and the fixing portion further comprises a fixing block extending from the blocking piece engaged in the fixing hole.

10. A mounting apparatus comprising:
a mounting case comprising a bottom plate; a mounting portion located on the bottom plate;
a mounting piece configured to be secured to a front end of an expansion card; the mounting piece is secured to the mounting case;
a securing member comprising a first securing panel, a second securing panel, and a rotating portion connected to the first securing panel and the second securing panel; the first securing panel is secured to the mounting portion; a positioning piece and a clipping block are located on the first securing panel; a clipping hole is defined in the second securing panel;
wherein the second securing panel is rotatable about the rotating portion relative to the first securing panel; the positioning piece abuts the expansion card to prevent the expansion card from moving in a direction that is substantially parallel to the bottom plate; the first securing panel and the second securing panel together sandwich a rear end of the expansion card therebetween, and the clipping block is clipped into the clipping hole, to prevent the expansion card from moving in a direction that is substantially perpendicular to the bottom plate.

11. The mounting apparatus of claim 10, wherein a clipping piece extends from the second securing panel and at an angle at the second securing panel, and the clipping hole is defined in the clipping piece.

12. The mounting apparatus of claim 10, wherein the first securing panel defines an engaging slot, and the second securing panel comprises an engaging portion engaged in the engaging slot.

13. The mounting apparatus of claim 10, wherein a fixing portion is located on the first securing panel and comprises a sliding portion extending from the first securing panel, the mounting portion comprises a sliding slot, and the sliding portion is slidably received in the sliding slot.

14. The mounting apparatus of claim 13, wherein the sliding slot is substantially U-shaped.

15. The mounting apparatus of claim 13, wherein the mounting portion comprises a fixing hole, and the fixing portion further comprises a fixing block extending from the blocking piece engaged in the fixing hole.

16. The mounting apparatus of claim 13, wherein the fixing portion further comprises a blocking piece connected to the sliding portion, the first securing panel abuts an inner surface of the bottom plate, and the blocking piece abuts an outer surface of the bottom plate, to prevent the securing member from moving in a direction that is substantially perpendicular to the bottom plate.

17. The mounting apparatus of claim 16, wherein the blocking piece is substantially parallel to the first securing panel.
